(19) United States
(12) Patent Application Publication
(10) Pub. No.: US 2015/0293163 A1
(43) Pub. Date: Oct. 15, 2015

(54) SYSTEM AND METHOD FOR MONITORING A MESHED CURRENT RETURN NETWORK OF AN AIRCRAFT

(71) Applicant: LABINAL POWER SYSTEMS, Blagnac (FR)

(72) Inventors: Thibaud Lebreton, Leguevin (FR); Arnaud Camille Ayme, Toulouse (FR)

(73) Assignee: LABINAL POWER SYSTEMS, Blagnac (FR)

(21) Appl. No.: 14/438,772

(22) PCT Filed: Oct. 21, 2013
(86) PCT No.: PCT/FR2013/052511

§ 371 Date: Apr. 27, 2015

(30) Foreign Application Priority Data
Oct. 29, 2012 (FR) 1260289

(51) Int. Cl. G01R 31/00; G01R 31/02

(52) U.S. Cl. CPC G01R 31/008; G01R 31/021

(57) ABSTRACT

A method for monitoring a meshed current-return network on an aircraft, the meshed network including at least two sub-networks electrically connected by a plurality of electrical junctions, the method including: measuring a current intensity in at least one electrical junction in which a nominal current is circulating for given flight conditions of the aircraft; wirelessly transmitting the measured current intensity value; receiving the measured current intensity; comparing the measured current intensity with a reference intensity of the nominal current determined for the electrical junction for the given flight conditions; and diagnosing soundness of the electrical junction following the comparing.

### GENERAL TECHNICAL FIELD AND PRIOR ART

The present invention relates to the field of electrical-current return systems, in particular for an aeronautical application.

An aircraft conventionally comprises a plurality of items of internal equipment (flight control device, various sensors, seats, lights, etc.) that are supplied electrically by a supply circuit that delivers an electrical current to said equipment. In order to afford an optimum supply to said equipment, it is necessary to provide a return for this electrical current, for example to the electrical earth of the supply circuit.

For an aircraft comprising a metal external casing, referred to as the “skin” by persons skilled in the art, the electrical current return is conventionally achieved by this metal casing, the electrical potential of which is connected to the electrical earth. As the external casing is easily accessible from any internal space of the aircraft, the current return does not present any difficulties. The metal external casing moreover provides discharge of the fault currents, the voltage reference for the electrical equipment, lightning protection, electromagnetic protection, the antenna earth reference, etc.

In order to reduce the weight of an aircraft and to improve its fatigue strength, an aircraft has been proposed with a structure made of a composite material. The aircraft comprises in particular an external casing made of composite material, for example made of carbon fibres. With reference to FIG. 1, an aircraft conventionally comprises a structural frame made of carbon 71 enveloped externally by a carbon skin 72. Such a composite casing 72 has reduced weight but does not conduct an electrical current, which makes any return of electrical current via the composite casing 72 impossible.

In order to eliminate this drawback, various metal elements of the aircraft (seat rails, cross-members or cable ducts, etc.) are put in a network to provide the current return. In practice, the current-return network is composed of a plurality of longitudinal sub-networks S1, S2, S3 that are superimposed vertically in the aircraft.

With reference to FIG. 1, by way of example, the current-return network 1 comprises:
a top longitudinal sub-network S1 composed of metal elements forming part of baggage compartment supports 73, cable ducts, central support 74, etc.;
a middle longitudinal sub-network S2 composed of metal elements forming part of seat rails 75, cable ducts, transverse beams 77, etc.; and
a bottom longitudinal sub-network S3 composed of metal elements forming part of cargo rails 76, cable ducts, transverse beams 78, etc.

In order to create an equipotential current-return network, the various longitudinal sub-networks S1-S3 are connected by electrical junctions 1, which may be rigid in order to provide mechanical holding and electrical or flexible connection.

A fault in the electrical junctions 1 may cause a current-return fault between the various longitudinal sub-networks S1-S3, which presents a drawback. In addition, electromagnetic protection would no longer be ensured.

Monitoring the electrical junctions 1 in a meshed current-return electrical network is difficult to implement. This is because the electrical junctions 1 are conventionally protected behind partitions or ceilings that clad the aircraft, which prevents inspection thereof by an operator from outside or inside the aircraft. To detect a fault, the only known solution requires dismantling the partitions and ceilings of the aircraft in order to observe the electrical junction 1 visually, which presents a major drawback since it is necessary to immobilise the aircraft.

One solution for overcoming this drawback would be to make direct measurements of resistance or voltage at the terminals of an electrical junction 1 when the aircraft is parked. Nevertheless, as the current-return network is meshed and redundant, degradation of a junction results in a very low difference in resistance, around 0.1 milliohms (with junction connected) to 1 milliohm (with junction disconnected), which are measurable only with very expensive instruments making it impossible to carry out overall monitoring of the meshed network. Furthermore, such a solution also requires removing the aircraft cladding.

To this end, in order to limit the risk of breakdown of the meshed current-return network, the electrical junctions are redundant, which increases the weight of the aircraft and presents a drawback.

### GENERAL DESCRIPTION OF THE INVENTION

In order to eliminate at least some of these drawbacks, the invention relates to a method for monitoring a meshed current-return network on an aircraft, the meshed network comprising at least two sub-networks electrically connected by a plurality of electrical junctions, the method comprising:
a step of measuring a current intensity in at least one electrical junction in which a nominal current is circulating for given flight conditions of the aircraft;
a step of wireless transmission of the measured current intensity value;
a step of receiving the measured current intensity;
a step of comparing the measured current intensity with a reference intensity of the nominal current determined for said electrical junction for said given flight conditions; and
a step of diagnosing the soundness of the electrical junction following the comparison step.

Sub-network of the meshed current-return network means both a single metal element (transverse beam, baggage compartment support, etc.) and a set of interconnected unit elements.

The step of measuring a current intensity when the aircraft is in flight makes it possible to measure intensity values in use that are in an intensity range that is simple to measure and requires no heavy measuring equipment.

Furthermore, the wireless transmission step makes it possible to avoid uncladding the aircraft to access the electrical junctions, which constitutes an advantage. The comparison and diagnosis steps improve the detection of faults, which is more precise and more reliable compared with a visual inspection as carried out in the prior art. Furthermore, detecting a fault is more rapid than in the prior art.

Furthermore, knowledge of the intensities circulating in the electrical junctions makes it possible to obtain a modelling of the current-return circulation in the meshed network, which is advantageous for improving the reliability and service life thereof. Improving the reliability of the meshed current-return network advantageously makes it possible to limit the number of redundant electrical junctions, which reduces the weight of the meshed network.

In a preferred manner, during the transmission step, the value of the current intensity measured is associated with an identifier of the junction on which the measurement was made. Thus it is possible to directly identify the junction that is defective during the diagnosis, which is advantageous when several junctions are tested simultaneously.

According to a preferred aspect of the invention, the reference intensity of the nominal current determined for said electrical junction for said given flight conditions is obtained by feedback over a plurality of flights of the aircraft. Thus it is possible to compare the change in the intensity circulating in an electrical junction during flights of the aircraft in order to detect any faults.

Preferably, the method comprises a step of determining a fault in said junction if its measured current intensity is less than a fault intensity threshold. If an electrical junction is defective, the nominal current-return can no longer circulate.

Preferably, the method comprises a step of confirming the soundness of said junction if its measured current intensity is above a soundness intensity threshold. If an electrical junction is sound, a high nominal-current current-return intensity is circulating in the electrical junction.

According to one aspect of the invention, the method comprises:
a step of measuring a current intensity in a plurality of electrical junctions in the region of the meshed network in which nominal currents circulate for given flight conditions;
a step of wireless transmission of the values of the current intensities measured;
a step of receiving the current intensities measured;
a step of comparing the current intensities measured with reference intensities of the nominal currents determined for said electrical junctions in the region for said given flight conditions; and
a step of determining a fault in a given junction in the region if its measured current intensity is less than its reference intensity of the nominal current while the other junctions in the region have a measured current intensity which is higher than their reference intensity of the nominal current.

The simultaneous monitoring of a plurality of junctions makes it possible to analyse the change in the distribution of the current return between the various junctions. This is because, when a fault appears on a junction, the current intensity that circulates in the electrical junction decreases while it increases in the adjacent junctions. Monitoring of a region of electrical junctions therefore increases the reliability of the monitoring because a larger number of items of information are available for establishing the diagnosis.

The invention also concerns a system for monitoring a meshed current-return network in an aircraft, the meshed network comprising at least two sub-networks connected electrically by a plurality of electrical junctions, the system comprising:
at least one intensity sensor associated with at least one electrical junction suitable for circulating a nominal current for given flight conditions of the aircraft, said intensity sensor being suitable for measuring a current intensity, said intensity sensor comprising means for wireless transmission of the value of the current intensity measured,
a maintenance computer comprising wireless data reception means, the maintenance computer being suitable for comparing the value of the current intensity measured with a reference intensity of the nominal current determined for said electrical junction for given flight conditions of the aircraft, so as to determine the soundness of the electrical junction.

Such a monitoring system is simple to implement and does not require uncladding the aircraft to reach the electrical junctions.

Preferably, said intensity sensor is passive, which facilitates installation thereof in the junction as well as maintenance.

Preferably, said intensity sensor comprises radio-wave transmission means, preferably of the RFID type, which are simple to implement.

According to a preferred aspect, said intensity sensor is suitable for taking an intensity measurement by means of a giant magnetoresistor. Such an intensity sensor is more compact and has high measurement precision.

Preferably, said intensity sensor comprises means for storing the measured intensity over a given period of time. Thus it is possible to limit the frequency of interrogation of the sensors, which is advantageous. Furthermore, this makes it possible to average the measured intensities in order to use them to establish the diagnosis.

According to one aspect of the invention, since a plurality of electrical junctions in the same region of the meshed network each comprise at least one intensity sensor, the maintenance computer is suitable for comparing the value of the current intensity measured for each electrical junction with a reference intensity of the nominal current determined for said electrical junction so as to determine the soundness of the electrical junction.

The simultaneous monitoring of a plurality of junctions makes it possible to analyse the change in the distribution of the current return between the various junctions. Monitoring a region of electrical junctions therefore increases the reliability of the monitoring because a larger number of items of information are available for establishing the diagnosis.

The invention also relates to a meshed current-return network in an aircraft, comprising at least one system as described above, as well as an aircraft comprising such a network.

### DESCRIPTION OF THE FIGURES

The invention will be better understood upon reading the following description given solely by way of example and with reference to the accompanying drawings, in which:

FIG. 1 is a cross section of an aircraft comprising a casing made of composite material (already commented on);

FIG. 2 is a schematic representation of the connection of two sub-networks in the current-return meshed network;

FIG. 3 is a schematic representation of the monitoring of a junction by the monitoring system according to the invention; and

FIG. 4 is a schematic representation of an embodiment of the invention.

It should be noted that the figures disclose the invention in detail in order to implement the invention, and said figures can of course serve to better define the invention where necessary.

### DESCRIPTION OF ONE OR MORE EMBODIMENTS

A monitoring system according to the invention will be described for an aircraft comprising a meshed current-return network comprising three sub-networks electrically connected by electrical junctions as set out in the preamble.

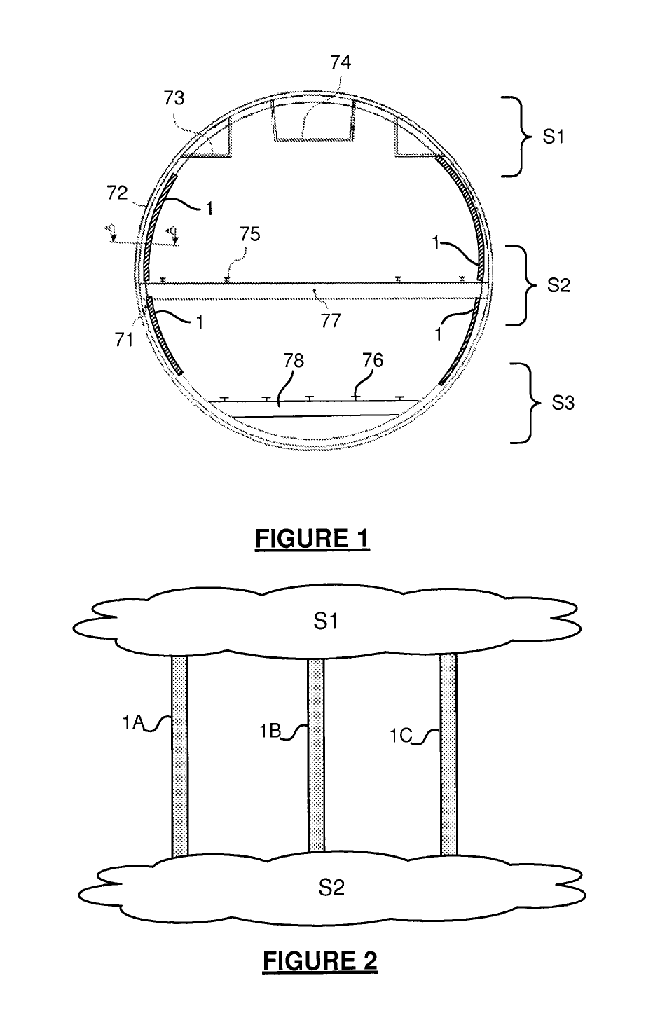

By way of example, with reference to FIG. 2, two adjacent sub-networks S1, S2 are connected by a plurality of electrical junctions 1A, 1B, 1C situated in the same region, that is to say close to one another in the meshed network. In this example, the electrical junctions 1A, 1B, 1C are situated behind partitions of the aircraft and are not accessible visually to an operator. An electrical junction 1A, 1B, 1C is in the form of an electrical energy transport cable.

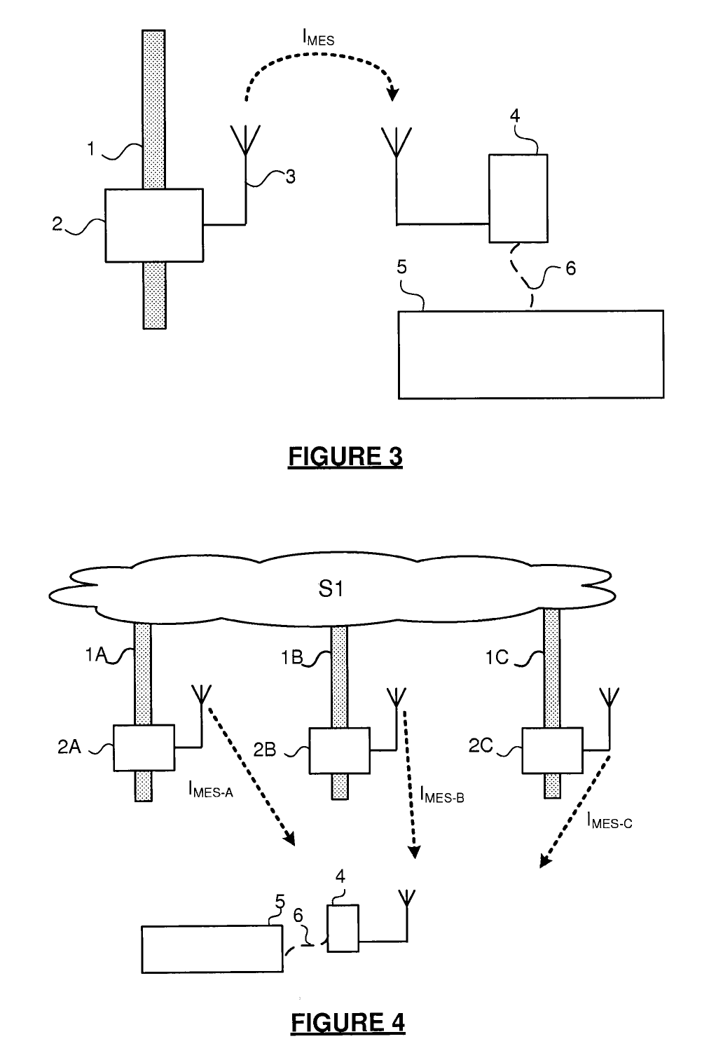

The monitoring of an electrical junction 1 is shown schematically in FIG. 3. When the aircraft is in flight, a nominal current circulates in the electrical junction 1 according to the flight conditions in order to provide the current return as set out previously. The value of the nominal current depends on the aircraft flight conditions. This is because, according to the flight conditions, the electrical equipment used is different, as is the electrical consumption thereof.

When the aircraft is in flight, the intensity values circulating in the electrical junction 1 belong to an intensity range that is simple to measure, not requiring any heavy equipment.

With reference to FIG. 3, the monitoring system according to the invention comprises an intensity sensor 2 that is associated with the electrical junction 1 in order to measure a current intensity I_{MES}, which is the intensity of the nominal current for given flight conditions of the aircraft.

An intensity sensor 2 can be mounted in or on the electrical junction 1 according to the nature of the intensity sensor 2.

In this example, the intensity sensor 2 is suitable for taking an intensity measurement by means of a giant magnetoresistor (not shown) mounted on the electrical junction 1. Such a magnetoresistor makes it possible to measure the AC and DC current precisely while having limited consumption. It goes without saying that the intensity could be measured differently.

The intensity sensor 2 comprises a chip which is able to acquire an intensity measurement I_{MES} at regular time intervals, each measurement being spaced apart by an acquisition period Pₐ. In this example, the acquisition period Pₐ is around one hour but it goes without saying that it could be different. Alternatively, the chip is suitable for acquiring a maximum intensity or an average intensity.

According to the invention, the intensity sensor 2 comprises means 3 for the wireless transmission of the value of the measured current intensity I_{MES} so as to communicate the measured intensity remotely, without removal of the aircraft partition. In this example, the intensity sensor 2 comprises radio-wave transmission means, preferably of the RFID type. It goes without saying that other transmission means could be suitable, for example of the WiFi, ZigBee, Bluetooth, WLAN type, etc. Preferably the transmission means 3 are suitable for transmitting the measured intensities I_{MES} on request.

Preferably, the intensity sensor 2 is configurable remotely, the transmission means 3 then being suitable for receiving configurations. Such configurations make it possible for example to modify the acquisition period Pₐ.

Preferably, the intensity sensor 2 comprises means for storing the intensities measured over a period of time with a view to transmission thereof, preferably a read only memory. Such storage means make it possible to store a large number of intensities to allow intensities to be transmitted less frequently than the acquisitions are made.

Preferably, the intensity sensor 2 is passive, that is to say it does not comprise electrical energy supply means that are particular to it. Transmission means of the RFID type are thus favoured. Alternatively, the intensity sensor is able to recover energy radiated by the electrical junction 1 or is able to be remotely supplied. To this end and preferably, the intensity sensor comprises remote-supply means of the RFID type. It nevertheless goes without saying that the intensity sensor 2 could, alternatively, be connected to a cell/battery. Such an active intensity sensor 2 is favoured for implementing transmission means of the WiFi, ZigBee, Bluetooth, WLAN type, etc. A supply battery needs to be changed, which may extend the aircraft maintenance steps.

Still with reference to FIG. 3, the monitoring system according to the invention comprises wireless data reception means that, in this example, are in the form of a portable reader 4 comprising radio-wave reception means so as to store the intensities I_{MES} sent by the intensity sensor 2. Preferably, the portable reader 4 comprises a storage memory.

The portable reader 4 is suitable for being connected to a maintenance computer 5 via connection means 6 that may be cabled or wireless. The maintenance computer 5 comprises a database that supplies the value of the nominal current in a given electrical junction 1 for given flight conditions. Preferably, the database is obtained by feedback or simulation.

The maintenance computer 5 is suitable for comparing the value of the measured current intensity I_{MES} of the electrical junction 1 with a reference intensity of the nominal current I_{REF} determined for said electrical junction 1 so as to determine the soundness of the electrical junction 1. Preferably, the comparisons are made on the basis of average or maximum intensity values that are most relevant.

In this example, the maintenance computer 5 diagnoses the soundness of the electrical junction 1 by means of software that compares the measured intensity I_{MES} with the reference intensity I_{REF} for the given flight conditions in order to determine whether the measured intensity I_{MES} is characteristic of a fault on the electrical junction 1. It goes without saying that the diagnosis could also be made directly by the portable reader 4.

If the electrical junction 1 is defective, the measured intensity I_{MES} will be less than its reference intensity I_{REF}, the current return being more difficult through the defective junction because of the increase in its internal resistance. Conversely, if the measured intensity I_{MES} is higher than its reference intensity I_{REF}, this means that another electrical junction in the region is defective, which obliges the current return to circulate more greatly on the sound electrical junctions.

Thus the monitoring of the change in difference between the measured intensity I_{MES} and the reference intensity I_{REF} for a given electrical junction 1 makes it possible to detect and predict any fault in said junction 1 or an adjacent junction. The comparison can be made on the basis of the current intensity values, the average intensity values or the maximum intensity values. By means of the monitoring of the change in the difference in intensities, it is possible to monitor a drift in the average or maximum intensity over time and thus to anticipate the maintenance operation on the electrical junction 1 before the fault is effective.

Alternatively, the maintenance computer 5 is suitable for detecting a fault in the electrical junction 1 if the measured intensity is below a fault intensity threshold S_{OFF}. This is because, if the drop in intensity measured is too high, this necessarily represents a fault in the electrical junction that prevents any passage of current. In this example, the fault intensity threshold S_{OFF} is around 20% (preferably 10%) of the maximum reference intensity for the same flight conditions.

In addition, the maintenance computer 5 is suitable for confirming the soundness of the electrical junction 1 if the intensity measured is above a soundness intensity threshold S_{ON}. This is because, if the measured intensity is high, this necessarily means that the electrical junction 1 allows an effective return of the current. In this example, the soundness intensity threshold S_{ON} is equal to 80% of the maximum reference intensity for the same flight conditions.

The use of fault S_{OFF} and soundness S_{ON} thresholds makes it possible to obtain a direct and rapid diagnosis of the soundness of the electrical junction 1. If the measured intensity lies between the fault S_{OFF} and soundness S_{ON} thresholds, additional tests may be implemented in order to obtain a reliable diagnosis of the electrical junction 1.

Preferably, the soundness intensity threshold S_{ON} is equal to that of the fault threshold S_{OFF}, that is to say they are equal to approximately 10% of the maximum reference intensity for the same flight conditions. Such an implementation makes it possible to detect defective junctions 1 reliably and quickly, the other junctions being considered to be sound.

Independently of the monitoring device set out above, the invention also relates to a monitoring method comprising:
a step of measuring a current intensity in the electrical junction in which a nominal current is circulating so as to allow a measurement in a range of intensities not requiring heavy measurement means;
a step of wireless transmission of the current intensity value measured so as to allow easy and rapid measurement;
a step of receiving the current intensity measured;
a step of comparing the measured current intensity with a reference intensity of the nominal current determined for said electrical junction for said given flight condition; and
a step of diagnosing the soundness of the electrical junction following the comparison step.

Preferably, for a plurality of electrical junctions in the same region of the meshed electrical network, the method comprises:
a step of measuring a current intensity in a plurality of electrical junctions in a region of the meshed network in which nominal currents are circulating;
a step of wireless transmission of the values of the measured current intensity;
a step of receiving the measured current intensities;
a step of comparing the measured current intensities with reference intensities of the nominal currents determined for said electrical junctions of the region for said given flight conditions; and
a step of determining a fault in a given junction in the region if its measured current intensity is below its reference intensity of the nominal current while the other junctions in the region have a measured current intensity which is higher than their reference intensity of the nominal current.

An embodiment of the invention will now be set out with reference to FIG. 4.

To monitor the state of the electrical junctions 1A, 1B, 1C connecting the meshed electrical sub-networks S1, S2 (not shown), an operator moves about in the aircraft with the portable reader 4. The electrical junctions 1A, 1B, 1C belong in this example to the same region. If one of the electrical junctions 1A, 1B, 1C is defective (for example the junction 1C), the current return is then effected by the other electrical junctions (in our example by 1A, 1B).

The electrical junctions 1A, 1B, 1C are connected respectively to intensity sensors 2A, 2B, 2C, which measure respectively intensities I_{MES-A}, I_{MES-B}, I_{MES-C} periodically and record them in their respective storage means. The measurements of the intensities I_{MES-A}, I_{MES-B}, I_{MES-C} are made during the flight of the aircraft for given flight conditions in order to ensure that a current return of a given value exists between the meshed electrical sub-networks S1, S2.

When the operator is situated at a distance of around one metre from the first junction 1A to be monitored, the portable reader 4 requests the measured intensities I_{MES-A} that are stored in the storage means of the intensity sensor 2A. These are then received by the portable reader 4 wirelessly via the transmission means of the intensity sensor 2A. Thus it is not necessary to remove the aircraft partitions or to know precisely the location of the electrical junction 1A.

In this example, the maintenance computer 5 is connected directly to the portable reader 4 by a communication cable 6. The maintenance computer 5 reads the measured intensities I_{MES-A} and compares them, firstly, with the fault threshold S_{OFF} and the soundness threshold S_{ON}. In this example, the measured intensities I_{MES-A} lie between the two thresholds S_{ON}, S_{OFF}, which does not make it possible to obtain an immediate diagnosis of the soundness of the first junction 1A.

The maintenance computer 5 compares the measured intensities I_{MES-A} with reference intensities I_{REF-A} of the first junction A obtained by feedback under similar flight conditions. Following the comparison, it appears that the measured intensities I_{MES-A} are higher than the reference intensities I_{REF-A}, which shows a drift in intensity. By repeating the monitoring method at regular time intervals, the operator can follow the change in the drift in intensity I_{MES-A} of the first junction and predict the appearance of any fault.

According to the method, the operator then monitors the electrical junctions 1B, 1C in the same region. In this example, following the comparisons, it appears that:
the measured intensities I_{MES-B} are higher than the reference intensities I_{REF-B}, and
the measured intensities I_{MES-C} are lower than the reference intensities I_{REF-C}.

As the electrical junctions 1A, 1B, 10 belong to the same region of the meshed network, the maintenance computer 5 deduces therefrom that the third electrical junction 10 is defective, which increases the current return via the first electrical junction 1A and the second electrical junction 1B.

The monitoring method is simple to implement and makes it possible to increase the reliability of an aircraft without requiring immobilisation thereof for long periods. Furthermore, advantageously, it is possible to predict the appearance of a fault at a junction and thus to carry out a maintenance step before the fault becomes effective.

Advantageously, by virtue of the monitoring system, it is possible to model the circulation of the current return in the meshed network and thus improve its structure in order to reduce its weight and bulk.

1-12. (canceled)

13. A method for monitoring a meshed current-return network on an aircraft, the meshed network including at least two sub-networks electrically connected by a plurality of electrical junctions, the method comprising:
measuring a current intensity in at least one electrical junction in which a nominal current is circulating for given flight conditions of the aircraft;
wirelessly transmitting the measured current intensity value;
receiving the measured current intensity;
comparing the measured current intensity with a reference intensity of the nominal current determined for the electrical junction for the given flight conditions; and
diagnosing soundness of the electrical junction following the comparing.

14. A monitoring method according to claim 13, wherein the reference intensity of the nominal current determined for the electrical junction for the given flight conditions is obtained by feedback over a plurality of flights of the aircraft.

15. A monitoring method according to claim 13, further comprising determining a fault in the junction if its measured current intensity is lower than a fault intensity threshold.

16. A monitoring method according to claim 13, further comprising confirming the soundness of the junction if its measured current intensity is higher than a soundness intensity threshold.

17. A monitoring method according to claim 13, further comprising:
measuring a current intensity in a plurality of electrical junctions in a region of the meshed network in which nominal currents circulate for given flight conditions;
wirelessly transmitting the values of the current intensities measured;
receiving the current intensities measured;
comparing the current intensities measured with reference intensities of the nominal currents determined for the electrical junctions in the region for the given flight conditions; and
determining a fault in a given junction in the region if its measured current intensity is less than its reference intensity of the nominal current while the other junctions in the region have a measured current intensity which is higher than their reference intensity of the nominal current.

18. A system for monitoring a meshed current-return network in an aircraft, the meshed network comprising at least two sub-networks connected electrically by a plurality of electrical junctions, the system comprising:
at least one intensity sensor associated with at least one electrical junction configured to circulate a nominal current for given flight conditions of the aircraft, the intensity sensor configured to measure a current intensity, the intensity sensor comprising means for wireless transmission of the value of the current intensity measured; and
a maintenance computer comprising wireless data reception means, the maintenance computer configured to compare a value of the current intensity measured with a reference intensity of the nominal current determined for the electrical junction for given flight conditions of the aircraft, to determine soundness of the electrical junction.

19. A system according to claim 18, wherein the intensity sensor is passive.

20. A system according to claim 18, wherein the intensity sensor comprises radio-wave transmission means, or is of RFID type.

21. A system according to claim 18, wherein the intensity sensor is configured to take an intensity measurement by a giant magnetoresistor.

22. A system according to claim 18, wherein a plurality of electrical junctions in a same region of the meshed network each comprise at least one intensity sensor, and the maintenance computer is configured to compare the value of the current intensity measured for each electrical junction with a reference intensity of the nominal current determined for the electrical junction to determine the soundness of the electrical junction.

23. A meshed current-return network in an aircraft, comprising at least one system according to claim 18.

24. An aircraft, comprising a meshed current-return network according to claim 23.
